(19) United States
(12) Patent Application Publication
(10) Pub. No.: US 2026/0164967 A1
(43) Pub. Date: Jun. 11, 2026

(54) DISPLAY DEVICE

(71) Applicant: LG Display Co., Ltd, Seoul (KR)

(72) Inventors: In Tae KO, Paju-si (KR); Kwang Hyun BAEK, Paju-si (KR)

(21) Appl. No.: 19/376,214

(22) Filed: Oct. 31, 2025

(30) Foreign Application Priority Data
Dec. 6, 2024 (KR) 10-2024-0180885

(51) Int. Cl. H10K 59/131; H10K 59/126; H10K 59/80

(52) U.S. Cl. CPC H10K 59/131; H10K 59/126; H10K 59/873

(57) ABSTRACT

A display device includes a substrate including a display area including a plurality of subpixels and a non-display area outside a periphery of the display area, a power voltage line formed in a first mesh shape and disposed in the non-display area, an encapsulation layer provided in an entirety of the display area and a part of the non-display area in which the power voltage line is disposed, and a light shielding layer disposed on the encapsulation layer to overlap the power voltage line.

### CROSS REFERENCE TO RELATED APPLICATIONS

Pursuant to 35 U.S.C. § 119(a), this application claims the benefit of an earlier filing date and right of priority to Korean Patent Application No. 10-2024-0180885, filed on Dec. 6, 2024, the entire contents of which are hereby incorporated by reference as if fully set forth herein.

### TECHNICAL FIELD

The present disclosure relates to a display device.

### BACKGROUND

Display devices that display images in TVs, monitors, smartphones, tablets, and laptops are being used in various methods and forms.

These display devices do not require a separate light source but require compactness and clear color display, and accordingly, self-luminous display devices, such as organic light emitting display devices and quantum dot light emitting display devices, are being considered as competitive applications.

### SUMMARY

In an aspect of the present disclosure, a display device includes a substrate including a display area including a plurality of subpixels and a non-display area outside a periphery of the display area, a power voltage line formed in a first mesh shape and disposed in the non-display area, an encapsulation layer provided in an entirety of the display area and a part of the non-display area in which the power voltage line is disposed, and a light shielding layer disposed on the encapsulation layer to overlap the power voltage line.

The light shielding layer may be disposed in a second mesh shape to overlap an entirety of the power voltage line.

The light shielding layer may have a larger width in each area corresponding to the power voltage line.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate implementation(s) of the disclosure and together with the description serve to explain the principle of the disclosure. In the drawings:

FIG. 1 is a plan view showing an example of a display device according to one implementation of the present disclosure;

FIG. 2 is a circuit diagram of an example of one subpixel of FIG. 1;

FIG. 3 is an enlarged view of an example of area A of FIG. 1;

FIG. 4 is an example of a cross-sectional view taken along line I-I′ of FIG. 1;

FIG. 5 is an enlarged view of an example of area B of FIG. 1;

FIG. 6 is an example of a cross-sectional view taken along line II-II′ of FIG. 5;

FIG. 7 is a plan view showing an example of a light shielding layer corresponding to a power voltage line of FIG. 4;

FIGS. 8 to 10 are plan views showing examples of implementations of anode dummy patterns of FIG. 7; and

FIG. 11 is a cross-sectional view showing an example of a display device according to another implementation of the present disclosure.

### DETAILED DESCRIPTION

Implementations of the present disclosure can provide a display device having improved transparency and capable of eliminating a sense of heterogeneity between areas.

In general, a self-luminous display device has a plurality of subpixels on a substrate, and each subpixel has a light emitting diode with two electrodes facing each other and an emission layer interposed between the electrodes.

Transparent display devices are capable of simultaneously achieving both light emission and transparent display by employing such self-luminous display devices.

Implementations of the present disclosure can provide a display device that can achieve increased transmittance by increasing the transmittance of a non-display area including power voltage lines and circuits.

According to some implementations, a display device can increase a transmission area of a non-display area to have transmittance similar to that of a display area.

According to some implementations, a display device can mitigate reflection visibility due to metal patterns having connections with power voltage lines in a non-display area.

According to some implementations, a display device can provide increased pure transmittance without visibility, e.g., due to diffraction or interference, of an object or an image located on a surface of the display device opposite a display surface.

According to some implementations, a display device can reduce cathode resistance and improve image quality through power voltage lines and upper connection structures in a non-display area.

According to some implementations, a display device can help achieve implementation of an eco-friendly display device.

Additional advantages, aspects, and features of the disclosure will be set forth in part in the description which follows and in part will become apparent to those having ordinary skill in the art. The aspects and other advantages of the disclosure may be realized and attained by the structure particularly pointed out in the written description and claims hereof as well as the appended drawings.

Advantages and features of the disclosure, and implementation methods thereof, will be clarified through the following implementations described with reference to the accompanying drawings. However, the disclosure may be embodied in different forms and should not be construed as limited to the implementations set forth herein. Rather, these implementations are provided so that the disclosure will be thorough and complete, and will fully convey the scope of the disclosure to those skilled in the art. Further, the disclosure is defined only by the categories of the claims.

The same reference numerals designate the same constituent elements. Thicknesses, ratios, and dimensions of constituent elements may be exaggeratedly expressed in the drawings, for effective description of the technical content. In addition, the dimensions and scales of constituent elements shown in the drawings are different from actual dimensions and scales, for convenience of description and, as such, the dimension scales of constituent elements are not limited to those shown in the drawings.

It will be understood that, when one constituent element (or an area, a layer, a portion, or the like) is referred to as being “disposed on”, “connected to” or “coupled to” another constituent element, the one constituent element may be directly connected/coupled to the other constituent element, or a third constituent element may be disposed between the two constituent elements.

The term “and/or” is used to include one or more combinations of associated configurations.

It will be understood that, although the terms “first”, “second”, etc. may be used herein to describe various elements, these elements should not be limited by these terms. These terms are only used to distinguish one element from another. For example, a first element referred to in the following description may represent a second element, without departing from the scope of the disclosure. Similarly, the second element may represent the first element. Unless clearly used otherwise, singular expressions include a plural meaning.

Terms such as “below,” “lower,” “above,” and “upper” are used to describe the relationships between the components shown in the drawings. These terms are relative concepts and are explained based on the orientations indicated in the drawings. For instance, unless “directly” or “immediately” is used, one or more other components may be disposed between two parts. Spatially relative terms such as “below”, “beneath”, “lower,” “above,” and “upper” may be employed to easily describe the correlation between one device or component and other devices or components, as represented in the drawings. These spatially relative terms should be understood as encompassing different orientations of the devices when used or during operation, in addition to the directions shown in the drawings. For example, if the device in one of the drawings is turned over, elements described as “below” or “beneath” other elements would then be oriented “above” the other elements. Therefore, the exemplary term “below” may encompass both downward and upward directions.

In this specification, it is to be understood that a term, such as “include” or “have”, is intended to designate that a characteristic, a number, a step, an operation, an element, a part or a combination of them described in the specification is present, and does not preclude the presence or addition possibility of one or more other characteristics, numbers, steps, operations, elements, parts, or combinations thereof.

Features of various implementations of the present disclosure can be partially or overall coupled to or combined with each other, and can be variously inter-operated with each other and driven technically as those skilled in the art can sufficiently understand. The implementations of the present disclosure can be carried out independently from each other, or can be carried out together in a co-dependent relationship.

Hereinafter, a detailed description will be given of a display device according to implementations of the present disclosure in conjunction with the attached drawings.

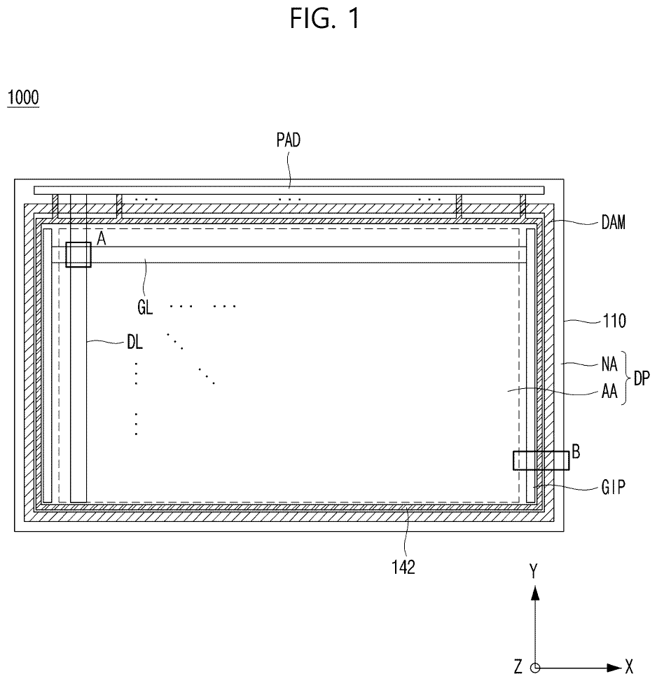

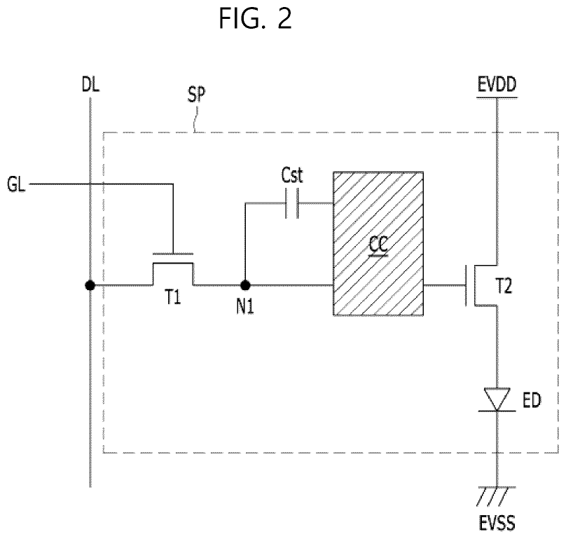

FIG. 1 is a plan view showing an example of a display device according to one implementation of the present disclosure, and FIG. 2 is an example of a circuit diagram of one subpixel of FIG. 1.

Referring to FIG. 1 and FIG. 2, a light emitting display device 1000 according to one implementation of the present disclosure may include a display panel DP. The display device 1000 can also include a case that accommodates side surfaces of the display panel DP and a lower portion of the display panel DP. A non-active area NA of the display panel DP may be shielded by the case or covered by a separate light shielding film. A printed circuit film and/or a battery may be provided between the lower portion of the display panel DP and the case.

The display panel DP may include a substrate 110 including an active area AA and the non-active area NA surrounding the active area AA, and drivers connected to the substrate 110. The active area AA is also referred to a display area, and the non-active area NA is also referred to a non-display area. In some implementations, the drivers may be provided in the non-active area NA of the substrate 110 to be integrated with the configuration of an array provided in the active area AA, and/or may be connected to a pad portion PAD of the substrate 110 in a chip on glass (COG) manner, and/or may be connected to a printed circuit board through a film or a connector in a chip on film (COF) manner on the pad portion PAD of the substrate 110. In some implementations, the drivers can include both a configuration integrated into the substrate 110 and the external configuration of a COG or a COF. In the example illustrated in FIG. 1, gate-in-panel (GIP)-type gate drivers GIP are shown in the non-active area NA as an example of the driver. As a data driver, a printed circuit board or a COF film including a driving IC may be connected to the pad portion PAD of the substrate 110.

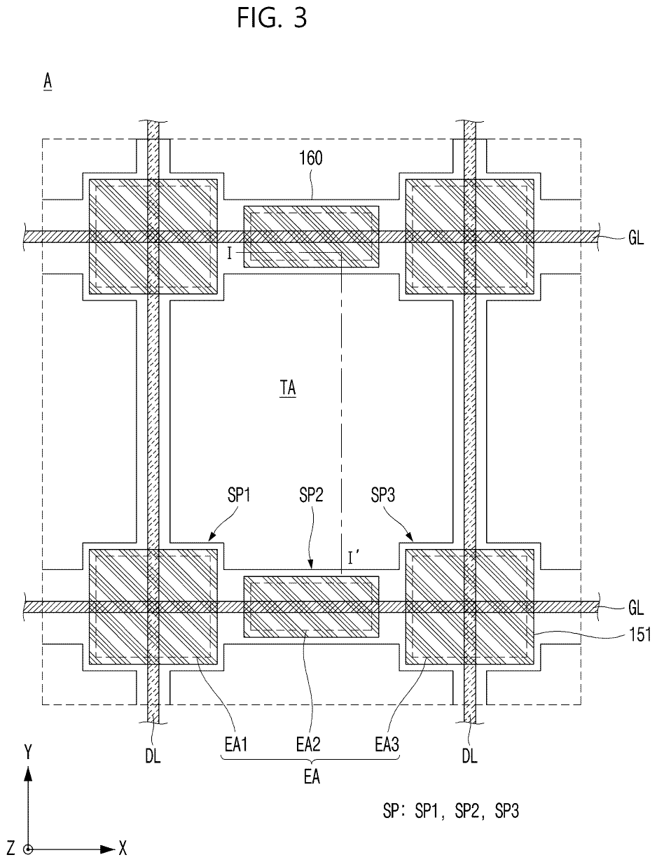

The active area AA is an area that displays an image. A plurality of gate lines GL and a plurality of data lines DL are disposed in the active area AA of the display panel DP. In addition, the active area AA may include subpixels SP: SP1, SP2, SP3 (in FIG. 3), each of which is connected to at least one of a plurality of gate lines GL and at least one of a plurality of data lines DL.

An area other than the active area AA may be the non-active area NA.

The non-active area NA may be disposed, for example, in an edge area surrounding the active area AA that displays an image. At least one driver for driving a plurality of subpixels SP may be disposed the non-active area NA. At least one driver may include a gate-in-panel (GIP). The gate-in-panel (GIP) may be connected to the plurality of gate lines GL of the active area AA and may sequentially supply gate voltage signals to the plurality of gate lines GL.

The gate driver GIP provided in the form of the gate-in-panel (GIP) outputs gate signals to the gate lines GL, for example, depending on a gate control signal input from a timing controller. The gate-in-panel (GIP) may include a plurality of transistors, and the plurality of transistors may be formed in the same process as transistors of the subpixels SP.

Various additional elements for driving the subpixels SP in the active area AA may be further disposed in the non-active area NA. For example, the non-active area NA may include a power voltage line 142 surrounding the edge of the display panel DP outside the gate drivers GIP. In the display device 1000 according to implementations of the present disclosure, the power voltage line 142 may be provided with openings, e.g., in a mesh shape having openings, so that light may be transmitted through the openings to increase the transmittance of the non-active area NA. In addition to the power voltage line 142 and the gate drivers GIP, the non-active area NA may include a plurality of clock lines and other signal lines. The plurality of clock lines and other signal lines may be conductively connected to the gate drivers GIP and/or the pad portion PAD.

The power voltage line 142 may be connected to a plurality of locations to receive a uniform power voltage supplied from the pad portion PAD.

At least one subpixel SP from among a plurality of pixels may include a first transistor T1, a second transistor T2, a storage capacitor Cst, a compensation circuit CC, and a light emitting element ED, as shown in FIG. 2.

For example, the first transistor T1 may be a switching transistor, and the second transistor T2 may be a driving transistor.

A first electrode (e.g., a drain electrode) of the first transistor T1 is conductively connected to the data line DL, and a second electrode (e.g., a source electrode) of the first transistor T1 is conductively connected to a first node N1. A gate electrode of the first transistor T1 is conductively connected to the gate line GL. The first transistor T1 transmits a data signal supplied through the data line DL to the first node N1 in response to a scan signal supplied through the gate line GL.

The storage capacitor Cst is conductively connected to the first node N1 and is charged with a voltage applied to the first node N1.

A first source-drain electrode (e.g., a drain electrode) of the second transistor T2 receives a high-potential voltage (high-potential driving voltage) EVDD, and a second source-drain electrode (e.g., a source electrode) of the second transistor T2 is conductively connected to an anode of the light emitting element ED. The second transistor T2 may control an amount of driving current flowing to the light emitting element ED depending on a voltage difference between a gate electrode and the source electrode.

A semiconductor layer of the first transistor T1 and/or the second transistor T2 may include silicon, such as amorphous silicon (a-Si), polycrystalline silicon (poly-Si), or low-temperature polycrystalline silicon (poly-Si), or may include an oxide semiconductor.

In the display device of implementations of the present disclosure, at least one of the transistors formed on the substrate 110 may include an oxide semiconductor layer. This can provide various advantages, e.g., advantages of stabilizing off characteristics compared to other materials, being formed at a low temperature, maintaining amorphous characteristics, and having high mobility.

The light emitting element ED outputs light corresponding to the driving current. The light emitting element ED has the anode connected to the second transistor T2 and a cathode connected to a first power voltage line, to which a ground voltage or a low-potential voltage (low-potential common voltage) EVSS is supplied. The light emitting element ED can output light corresponding to one color from among red, green, blue, and white in each subpixel.

The light emitting element ED may include the anode, an intermediate layer disposed on the anode, and the cathode. The intermediate layer can include at least one emission layer. In some implementations, when an electric field is formed between the anode and the cathode, the intermediate layer can be implemented to emit light of the same color for each subpixel, such as white light, or can be implemented to emit different colors for each subpixel SP, such as red, green, or blue light. In addition to the emission layer, the intermediate layer may include various kinds of common layers and functional layers, e.g., to efficiently supply holes and electrons to the emission layer. The cathode is connected to the (first) power voltage line to which a low-potential voltage EVSS or a ground voltage is supplied. In the second transistor T2 (which supplies the driving current), a side of the second transistor T2 that is not connected to the light emitting element ED may be connected to a second power voltage line, and may be supplied with a high-potential voltage EVDD. Further, the first power voltage line and the second power voltage line are respectively provided in each subpixel SP, and may have connections between the pad portion PAD and the active area AA at least in the non-active area NA. FIG. 1 illustrates, as an example, the power voltage line 142 that supplies a low potential voltage EVSS to the cathode, and for example, the power voltage line 142 may have a closed ring shape surrounding the entire active area AA. The cathode of the light emitting element ED is disposed to have a large area over the entire active area AA, and a common voltage is applied to the cathode. Therefore, in implementations where a uniform potential is maintained over the entire active area AA, the cathode can be connected to the power voltage line 142 at each side of the non-active area NA, without being biased toward a portion of the non-active area NA around the active area AA, in order to maintain a uniform low-potential voltage over the entire active area AA. In some scenarios, the power voltage line 142 that supplies the common voltage to the cathode having a large area may have a greater line width than other clock lines or signal lines. In some implementations, the power voltage line 142 can be disposed on each side of the substrate 110, e.g., to uniformly apply the common voltage. As an example, in FIG. 1, the power voltage line 142 can be disposed without disconnection to correspond to each side of the substrate 110. However, the display device according to the implementations of the present disclosure is not limited to the power voltage line 142 formed in a closed loop form, and other configurations can be implemented.

In some implementations, the power voltage line 142 is a line to which a low-potential common voltage is constantly and continuously supplied, and may have a greater line width than the clock lines or the signal lines to which a clock signal or a specific voltage is supplied at a specific time. In the display device 1000 according to one implementation of the present disclosure, the power voltage line 142 has a plurality of openings. For example, the power voltage line 142 can be implemented in a mesh shape including a plurality of openings, so that light transmission through the openings is possible. As such, the display device 1000 according to one implementation of the present disclosure may improve transmittance in the area of the power voltage line that occupies a greater width than other clock lines or signal lines in the non-active area NA and increase the transmittance of the non-active area NA. The power voltage line 142 and/or other signal lines may be formed with openings, e.g., in a mesh shape, corresponding to a bezel area where the pad portion PAD is not disposed among the non-active area NA of the substrate 110, to improve transmittance. In such scenarios, the display device 100 can obtain a visual effect similar to a bezel-less display, and in particular, the transmittance of a transparent display device can be improved by preventing the edge of the transparent display device from appearing opaque. The mesh shape provided in the power voltage line 142 may be applied to at least the left side and the right side of the substrate 110 when the substrate 110 has a substantially rectangular shape. The mesh shape may be applied only to some sides of the substrate 110 on which the power voltage line 142 is disposed. In a display device according to another implementation of the present disclosure, the mesh shape of the power voltage line 142 may also be applied to the lower side of the substrate 110. In a display device according to yet another implementation of the present disclosure, the mesh shape of the power voltage line 142 may also be applied to the upper side of the substrate 110. In some cases, the upper side of the substrate 110 includes the pad portion PAD, and a portion of the power voltage line 142 connected to the pad portion PAD does not employ the mesh shape, e.g., in order to prevent an increase in electrical resistance.

In some implementations, the structure of a line having openings of the display device 1000 can be applied not only to the power voltage line (to which the above-described low potential voltage EVSS is supplied), but can also be applied to the second power voltage line (to which the high potential voltage EVDD is supplied) or can be applied to other signal lines. In some implementations, the second power voltage line (to which the high potential voltage EVDD is supplied) or other signal lines do not surround the entire active area AA but instead are be provided only on some sides of the substrate 110.

A dam portion DAM can be configured to surround the power voltage line 142 in some implementations, e.g., to prevent overflow of a liquid component for an encapsulation layer that protects the light emitting elements. The dam portion DAM can be provided, for example, at the non-active area NA of the display device 1000.

In some implementations, the compensation circuit CC can be additionally provided in the subpixel SP to compensate for the threshold voltage of the second transistor T2, etc. The compensation circuit CC may include one or more transistors and capacitors, and can be configured in various ways depending on a compensation technique. The subpixel SP including the compensation circuit CC may include one of circuits of various structures having different numbers of transistors and/or capacitors, such as 3T1C, 4T2C, 5T2C, 6TIC, 6T2C, 7T1C, and 7T2C.

Among the transistors provided in the subpixel, the switching transistor may require high-speed driving for fast switching operation. The driving transistor may require high current output for high brightness expression by supplying high current to the light emitting element ED.

Further, the display device according to the implementations of the present disclosure has emission areas and transmission areas in the active area AA, and improves transmittance through the openings provided in the power voltage line in the non-active area NA. The specific configuration of the display device will be described.

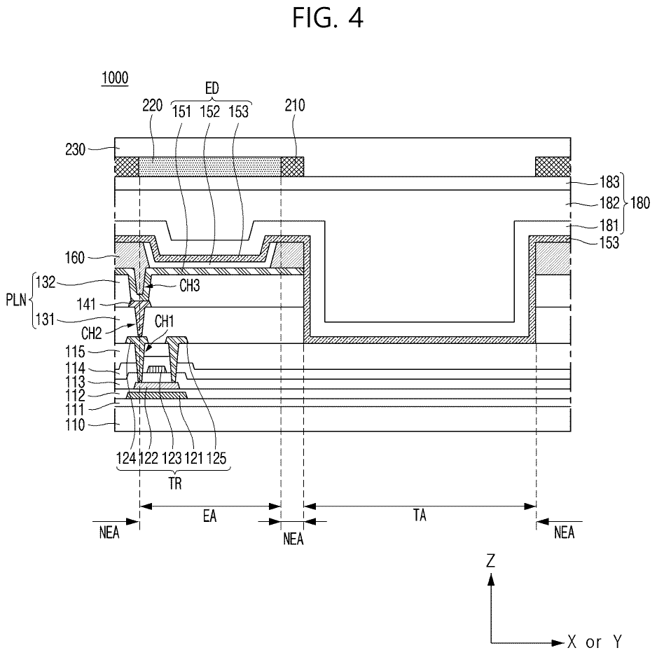

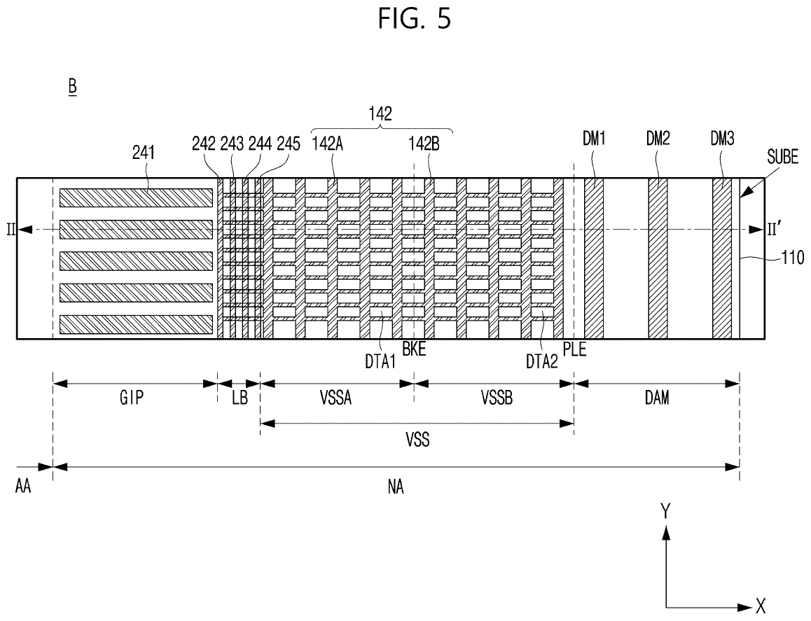

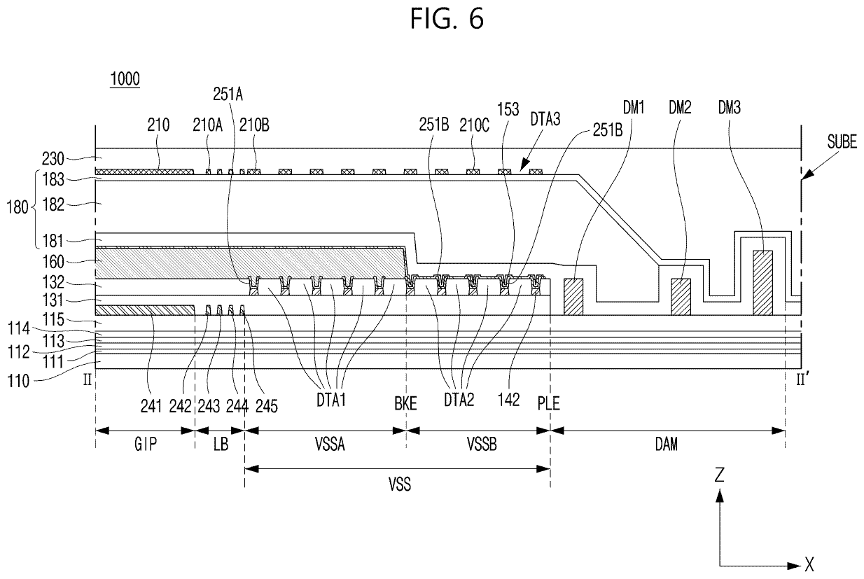

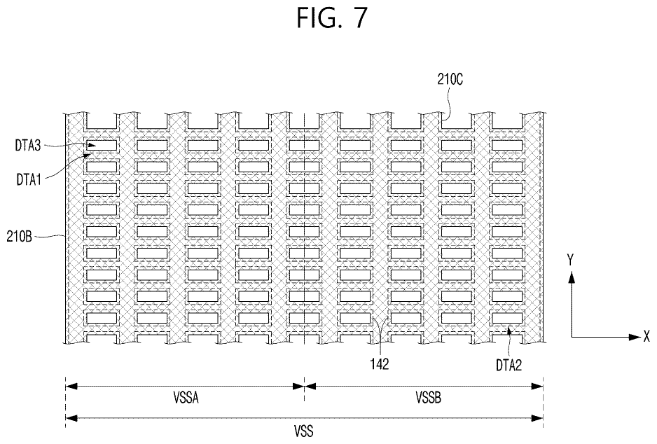

FIG. 3 is an enlarged view of an example of area A of FIG. 1. FIG. 4 is an example cross-sectional view taken along line I-I′ of FIG. 1. FIG. 5 is an enlarged view of an example of area B of FIG. 1. FIG. 6 is an example cross-sectional view taken along line II-II′ of FIG. 5. FIG. 7 is an example plan view showing a light shielding layer corresponding to the power voltage line of FIG. 4.

The display device 1000 according to one implementation of the present disclosure includes the substrate 110 including the active area AA including a plurality of subpixels SP1, SP2, and SP3 and the non-active area NA surrounding the active area AA, as shown in FIGS. 1 to 4, and the power voltage line 142 formed in a first mesh shape disposed in the non-active area NA, as shown in FIGS. 5 to 6.

The first mesh shape of the power voltage line 142 is configured such that, as shown in FIG. 5, lines in the X direction and lines in the Y direction are connected to intersect each other, and regions between the lines in the X direction and the lines in the Y direction define a plurality of openings DTA1 and DTA2.

The display device 1000 according to one implementation of the present disclosure may include a plurality of emission areas EA: EA1, EA2, and EA3 and a plurality of transmission areas TA in the active area AA, as shown in FIG. 3.

The transmission areas TA are disposed between the emission areas EA: EA1, EA2, and EA3 and do not overlap wiring lines, such as the gate lines GL and the data lines DL, to have transparency. The transmission areas TA can be disposed to be separate from the first electrodes 151. The first electrodes 151 of the light emitting element may not overlap he transmission areas.

The first electrode of the light emitting elements ED can be referred as an anode and the second electrode of the light emitting elements ED can be referred as a cathode.

Compared to the transmission areas TA, the emission areas EA: EA1, EA2, and EA3 may intersect with at least one of, for example, the gate lines GL disposed in the X direction and the data lines DL disposed in the Y direction. The emission areas EA: EA1, EA2, and EA3 are provided in an area where the wiring lines are located, so that the aperture ratio of the emission areas EA: EA1, EA2, and EA3 may be increased and a non-effective area may be reduced in the display device 1000.

In addition, a bank 160 is disposed between adjacent emission areas EA: EA1, EA2, and EA3, between the transmission areas TA, and between the emission areas EA: EA1, EA2, and EA3 and the transmission areas TA, thereby being capable of dividing the emission areas EA: EA1, EA2, EA3 and the transmission areas TA.

Each subpixel SP: SP1, SP2, or SP3 may have one of the emission areas EA: EA1, EA2, and EA3.

The emission areas EA1, EA2, and EA3 may emit, for example, red, green, and blue light. Although FIG. 3 illustrates an example in which the shape of the emission areas EA1, EA2, and EA3 is a rectangle, the implementations of the present disclosure are not limited thereto. The shape of the emission areas EA1, EA2, EA3 may be a polygon, such as a rectangle, a hexagon, an octagon, a decagon, or a dodecagon, and in some cases, at least one corner of the shape may be rounded. In addition, the dimensions of the emission areas EA1, EA2, and EA3 may vary depending on the efficiency of the light emitting elements ED disposed in the emission areas EA1, EA2, EA3. For example, if the efficiency of the light emitting element ED that displays a specific color is low, the dimensions of the emission area may be greater than those of other emission areas to compensate for the low efficiency.

Referring to FIG. 4, the structure of the active area AA including the configurations of the emission area EA and the transmission area TA will be described.

First, the detailed configuration of the emission area EA will be described.

Each emission area EA includes a transistor TR and the light emitting element ED on the substrate 110, and when an electrical signal is supplied through the transistor TR, light is emitted through the light emitting element ED.

The transistor (thin film transistor, TFT) TR may include, for example, a light shielding pattern 121, an active layer 122, a gate electrode 123, and first and second source-drain electrodes 124 and 125.

The substrate 110 functions to support and protect components disposed thereon. The substrate 110 may be transparent and may also have flexibility. The substrate 110 may be formed of, for example, glass or plastic.

In one implementation of the present disclosure, the substrate 110 may include a plurality of layers and, for example, may be configured in a form in which an interlayer inorganic film is disposed between different flexible substrates.

In one implementation of the present disclosure, the substrate 110 includes the emission areas EA and transmission areas TA that are spaced apart from each other, and the transmission area TA may be configured not to overlap components including light-blocking metal materials, such as wirings including the gate lines GL, and the data lines DL, and the transistor TR, so as to increase the pure transmittance of light passing through the substrate 110. Accordingly, an object or an image located below the substrate 110 may be observed from outside an uppermost component of the substrate 110. In contrast to the transmission area TA, the emission area EA may include the light emitting element ED, and may overlap the wirings including the gate line GL and the data line DL, and the transistor TR, which are components below the light emitting element ED. In some implementations, the light emitting element ED is formed by sequentially stacking a first electrode 151 provided for each subpixel, and an intermediate layer 152 and a second electrode 153 on the first electrode 151. The emission areas EA1, EA2, and EA3 emits light generated from the inside of the light emitting elements ED to above the second electrode 153, and an image depending on the operation of the light emitting elements ED may be observed from outside the uppermost component of the substrate 110.

The transistor (TFT) TR provided on the substrate 110 may be provided on a first insulating film 111 on the substrate 110. The first insulating film 111 may be one or more insulating films. The first insulating film 111 may be provided to prevent impurities from entering an array configuration on the substrate 110 from the substrate 110 and to protect the array configuration on the substrate 110.

The transistor TR may include the light shielding pattern 121 to prevent light transmitted from below the substrate 110 from entering the active layer 122. The light shielding pattern 121 may prevent abnormalities, such as photocurrent generation, by blocking transmission of light from below the substrate 110 to the transistor TR.

A second insulating film 112 that covers the first insulating film 111 provided with the light shielding pattern 121 and achieves surface planarization may be provided.

The first and second insulating films 111 and 112 may protect structures on the substrate 110, which are vulnerable to moisture penetration, from moisture penetrating the substrate 110 and planarizes the surface of the substrate 110.

The active layer 122 may be provided on the second insulating film 112. The active layer 122 may include a semiconductor material. The semiconductor material may include a silicon-based semiconductor material or an oxide-based semiconductor material.

A third insulating film 113 is provided on the second insulating film 112 provided with the active layer 122. The third insulating film 113 may function as a gate insulating film between the active layer 122 and the gate electrode 123.

A fourth insulating film 114 and a fifth insulating film 115 may be provided on the third insulating film 113 to cover the gate electrode 123. The fourth insulating film 114 and the fifth insulating film 115 may be provided as a single insulating film, in some cases. The fourth insulating film 114 and the fifth insulating film 115 may perform an interlayer insulating function between the gate electrode 123 and the first and second source-drain electrodes 124 and 125.

The fifth insulating film 115, the fourth insulating film 114, and the third insulating film 113 may have first contact holes CH1.

In addition, the first and second source-drain electrodes 124 and 125 formed of a first source-drain metal may be connected to both sides of the upper surface of the active layer 122 through the first contact holes CH1. One of the first and second source-drain electrodes 124 and 125 may be a source electrode and the other may be a drain electrode.

The light shielding pattern 121 may be connected to one of the first and second source-drain electrodes 124 and 125 for potential stabilization. Alternatively, the light shielding pattern 121 may be connected to the gate electrode 123 above the active layer 122 to function as a bottom gate of the transistor TR.

Further, each of the light shielding pattern 121, the gate electrode 123, and the first and second source-drain electrodes 124 and 125 may include one metal from among aluminum (Al), titanium (Ti), copper (Cu), chromium (Cr), molybdenum (Mo), and tungsten (W).

In addition to the transistor illustrated in FIG. 4, the subpixel may further include another transistor having a different function. The storage capacitor that stores the storage voltage of the subpixel may be formed together with the transistors included in the subpixel in the same process.

Each of the first to fifth insulating films 111, 112, 113, 114, and 115 may be an inorganic insulating film. The first to fifth insulating films 111, 112, 113, 114, and 115 may include, for example, a silicon oxide (SiOₓ) film, a silicon nitride (SiNₓ) film, a silicon oxynitride film, or a multilayer film thereof.

An organic film PLN including a first organic film 131 and a second organic film 132 that protect the transistor (TFT) TR may be provided on the transistor TR.

The first organic film 131 may be disposed on the transistor TR or the fifth insulating film 115 to protect the transistor TR and alleviate a step caused by the transistor TR.

In addition, a connection electrode 141 connected to the first source-drain electrode 124 may be further provided on the first organic film 131.

The connection electrode 141 may have a second contact hole CH2 in the first organic film 131 to expose a portion of the upper surface of the first source-drain electrode 124, and may be connected to the first source-drain electrode 124 through the second contact hole CH2.

The second organic film 132 may be provided on the first organic film 131. The second organic film 132 may be provided with a third contact hole CH3 that exposes a portion of the upper surface of the connection electrode 141. The first electrode 151 of the light emitting element ED may be connected to the connection electrode 141 through the third contact hole CH3.

Further, the first and second source-drain electrodes 124 and 125 and the connection electrode 141 of the above-described transistor (TFT) TR may be located in the same layer as other signal lines, the clock lines, and the power voltage line provided in the active area AA and the non-active area NA.

The first and second organic films 131 and 132 may cover the transistor TR and be disposed on the fifth insulating film 115 to provide a flat surface.

Each of the first organic film 131 and the second organic film 132 may include an organic material. The organic material may include at least one of acrylic resins, phenolic resins, polyimide resins, unsaturated polyester resins, polyamide resins, benzocyclobutene, polyphenylene resins, or polyphenylene sulfide resins.

In addition to the above-described first to fifth insulating films 111, 112, 113, 114, and 115, organic or inorganic films having various functions may be further disposed between the substrate 110 and the first organic film 131.

The light emitting element ED is disposed on the second organic film 132. The light emitting element ED may be conductively connected to the transistor TR through the organic film PLN. The light emitting element ED includes the first electrode 151, the intermediate layer 152, and the second electrode 153.

The first electrode 151 may function as an anode. The first electrode 151 may be connected to the connection electrode 141 through the third contact hole CH3 in the second organic film 132, and the connection electrode 141 may be connected to the first source-drain electrode 124 through the second contact hole CH2 to be connected to the transistor TR. In some cases, the connection electrode 141 and the second organic film 132 may be omitted, and the first source-drain electrode 124 and the first electrode 151 of the light emitting element ED may be directly connected through a contact hole provided in the first organic film 131.

The first electrode 151 may include a metal material having high reflectivity. For example, the first electrode 151 may be formed as a multilayer structure, such as a stacked structure of aluminum (Al) and titanium (Ti) (Ti/Al/Ti), a stacked structure of aluminum (Al) and ITO (ITO/AI/ITO), an APC (Ag/Pd/Cu) alloy, and a stacked structure of an APC alloy and ITO (ITO/APC/ITO), or a stacked structure of silver (Ag) and a molybdenum titanium alloy (Ag/MoTi), or may include a single-layer structure formed of one selected from silver (Ag), aluminum (Al), molybdenum (Mo), gold (Au), magnesium (Mg), calcium (Ca), and barium (Ba), or an alloy material of two or more selected therefrom. The first electrode 151 may be referred to as a reflective electrode or an anode.

The intermediate layer 152 is provided on the first electrode 151. The intermediate layer 152 may include a hole injection layer, a hole transport layer, an organic emission layer, an electron transport layer, and an electron injection layer. In some cases, the intermediate layer 152 may include a plurality of stacks and a charge generation layer between the stacks. If the intermediate layer 152 includes a plurality of stacks, each stack may include at least one emission layer, a hole transport common layer under the emission layer, and an electron transport common layer on the emission layer. FIG. 4 shows an example in which the intermediate layer 152 is disposed only in the emission area EA. However, the display device 1000 according to one implementation of the present disclosure is not limited thereto. The emission layer among the intermediate layer 152 may be patterned to correspond to the emission area EA. The hole injection layer, the hole transport layer, the electron transport layer, and the electron injection layer other than the emission layer among the intermediate layer may be provided as common layers over the plurality of subpixels SP. In some cases, at least one of the common layers may be formed to extend to the transmission area TA.

The edge of the first electrode 151 may overlap the bank 160. An area of the first electrode 151 exposed from the bank 160 may be defined as the emission area EA. The bank 160 may be located not only around the emission area EA but also around the transmission area TA. That is, the bank 160 may be disposed in areas between a plurality of different emission areas EA: EA1, EA2, EA3, between adjacent transmission areas TA, and between the emission areas EA and the transmission areas TA.

The bank 160 may include a transparent insulating bank and/or an opaque insulating bank. The opaque insulating bank may include a black material. If the bank 160 includes an opaque insulating bank, viewing angle characteristics may be improved by preventing oblique light passing through a side portion in the emission area EA from being visible, and the transparency of the transmission area TA may be prevented from being reduced by light emitted from the adjacent emission area EA.

An area where the bank 160 is located may be a non-emission area NEA.

When voltage is applied to the first electrode 151 and the second electrode 153, holes and electrons move to the organic emission layer through the hole injection layer, the hole transport layer, the electron injection layer, and the electron transport layer, respectively, and the holes and the electrons combine with each other to form excitons in the organic emission layer, and the excitons drop from the excited state to the ground state, thereby causing light emission.

Each layer among the intermediate layer 152 may be provided in common throughout the entire active area AA. In some cases, one layer among the intermediate layer 152 may be selectively provided in the emission areas EA1, EA2, and EA3. In the light emitting element ED, the intermediate layer 152 may have a tandem configuration in which a plurality of stacks, each of which includes an emission layer, a hole transport common layer related to hole transport under the emission layer, and an electron transport common layer related to electron transport on the emission layer, are provided, and a charge generation layer is provided between the plurality of stacks. In the tandem configuration, each layer including the charge generation layer of the intermediate layer 152 may be a common layer disposed over the entire surface of the active area AA.

The intermediate layer 152 may include at least one emission layer of a red emission layer that emits red light, a green emission layer that emits green light, or a blue emission layer that emits blue light. As in the intermediate layer 152 of FIG. 4, the red emission layer, the green emission layer, or the blue emission layer may be disposed on the first electrode 151 for each subpixel SP. The red emission layer may be patterned to be disposed in red subpixels, the green emission layer may be patterned to be disposed in green subpixels, and the blue emission layer may be patterned to be disposed in blue subpixels, but the present disclosure is not limited thereto, and at least two or more organic emission layers among the red emission layer, the green emission layer, and the blue emission layer may be staked and disposed in one subpixel SP.

The intermediate layer 152 may be a white emission layer that emits white light. In this case, the organic emission layer of the intermediate layer 152 may be a common layer that is disposed in common over the subpixels SP rather than in a pattern form.

The second electrode 153 may function as a cathode in the light emitting element ED. The second electrode 153 may be a common layer that is disposed in common over the subpixels SP and applies the same voltage to the subpixels SP. For this purpose, the second electrode 153 may be disposed to extend from the active area AA to a portion of the non-active area NA.

The second electrode 153 may be a transmissive electrode. The second electrode 153 may include a transparent conductive material (TCO), such as indium tin oxide (ITO) or indium zinc oxide (IZO) that may transmit light, or a semi-transmissive conductive material, such as magnesium (Mg), silver (Ag), or an alloy of magnesium (Mg) and silver (Ag). When the second electrode 153 includes a semi-transmissive conductive material, the light emission efficiency may be increased by microcavities. When the second electrode 153 includes a semi-transmissive conductive material, the thickness of the second electrode 153 may be thin enough to transmit light. For example, the thickness of the second electrode 153 may be 200 Å or less.

The first electrode 151 may include a reflective electrode to prevent light generated from the intermediate layer 152 from being transmitted to light shielding components below the first electrode 151. The light generated from the intermediate layer 152 may resonate between the second electrode 153 and the first electrode 151 and finally be emitted upwardly through the second electrode 153. Since the first electrode 151 includes a reflective electrode, even if the first electrode 151 overlaps the wirings and the transistors (TFTs), the light emitted from the light emitting elements ED in the emission areas EA: EA1, EA2, and EA3 may be visible from above without affecting the disposition of the wirings and the transistors (TFTs).

The transmission area TA does not have the first electrode 151, compared to the emission area EA. The intermediate layer 152 and the second electrode 153 may be provided independently in the transmission area TA. At least one of the hole injection layer, the hole transport layer, the electron transport layer, or the electron injection layer among the intermediate layer 152 may extend laterally from the emission area EA1, EA2, or EA3 and may be provided in the transmission area TA. As shown in FIG. 4, the second electrode 153 may be provided in the transmission area TA. In some cases, the second electrode 153 may be omitted from the transmission area TA to increase the transmittance of the transmission area TA.

When the intermediate layer 152 and the second electrode 153 are provided in the transmission area TA, use of a fine metal mask (FMM) requiring fine openings when forming each layer may be omitted, and yield improvement and process simplification are expected.

An encapsulation layer 180 is provided on the light emitting element ED to protect and seal the light emitting element ED.

The encapsulation layer 180 may be provided as a single film or include a plurality of films. When the encapsulation layer 180 includes a plurality of films, for example, inorganic encapsulation layers 181 and 183 and an organic encapsulation layer 182 may be disposed in an alternating manner of one or more pairs. The uppermost and lowermost layers of the encapsulation layer 180, which are inorganic encapsulation layers, may be advantageous in preventing penetration of external air, moisture, etc. from the outside.

The encapsulation layer 180 planarizes surface roughness caused by the light emitting element ED.

A light shielding layer 210 corresponding to the non-emission area NEA and a color filter 220 corresponding to at least the emission area EA may be provided on the encapsulation layer 180. In some cases, the color filter 220 may extend to the non-emission area NEA so as to overlap the light shielding layer 210. The light shielding layer 210 and the color filter 220 may have functions of absorbing external light and preventing external light reflection. A protective film 230 may be further provided to cover the light shielding layer 210 and the color filter 220. The protective film 230 is transparent and has an upper surface planarization function to ensure that the display device 1000 has a flat surface without surface roughness when observed from the outside. The protective film 230 may be a transparent organic film. The protective film 230 may also function as a cover film.

The transmission area TA will be described.

The transmission area TA may include, the first to fifth insulating films 111, 112, 113, 114, and 115, the second electrode 153, the encapsulation layer 180, and the protective film 230 on the substrate 110, which are included in the emission area EA.

As shown in FIGS. 3 and 4, the transmission area TA excludes light-shielding metals, such as the gate line GL and the data line DL, to maximize the transmittance of light passing from the bottom to the top of the substrate 110. In this case, the organic film PLN may be omitted from the transmission area TA to increase lower light transmittance.

In the display device 1000 according to one implementation of the present disclosure, at least one of the first to fifth insulating films 111, 112, 113, 114, and 115 or the first and second organic films 131 and 132 is removed from the transmission area TA to reduce a path of an area where light propagates in the transmission area TA, thereby being capable of increasing the transparency of the light. FIG. 4 shows an example in which the first and second organic films 131 and 132 are omitted from the transmission area TA, but the implementations of the present disclosure are not limited thereto. One of the first to fifth insulating films 111, 112, 113, 114, and 115 may be omitted instead of the first and second organic films 131 and 132 in the transmission area TA, or at least one of the first to fifth insulating films 111, 112, 113, 114, and 115 may be omitted together with the first and second organic films 131 and 132 in the transmission area TA.

Further, among the configuration of the light emitting element ED, the intermediate layer 152 and the second electrode 153 may be independently disposed in the transmission area TA or omitted in the transmission area TA. FIG. 4 shows a state in which the second electrode 153 is also located in the transmission area TA, but the implementations of the present disclosure are not limited thereto. When the second electrode 153 is provided in the transmission area TA, the second electrode 153 may be formed to be integrated over the entire active area AA, and the resistance of the second electrode 153 may be reduced as the area of the second electrode 153 increases, and accordingly, the potential of the second electrode 153 may be constant in the respective areas, thereby improving image quality.

The display device 1000 according to one implementation of the present disclosure is characterized in that the transmittance even in the non-active area NA is increased.

For this purpose, the display device 1000 according to one implementation of the present disclosure may include the power voltage line 142 formed in the first mesh shape in the non-active area NA, and the encapsulation layer 180 in the entire active area AA and the non-active area NA where the power voltage line 142 is disposed, and the light shielding layer 210 disposed on the encapsulation layer 180 to overlap the power voltage line 142.

The first mesh shape of the power voltage line 142 indicates a structure in which a plurality of horizontal lines and a plurality of vertical lines with thin line widths are repeated. Openings DTA1 and DTA2 are provided between the horizontal lines and the vertical lines with the thin line widths of the power voltage line 142 in a power voltage line area VSS among the non-active area NA, and transmittance in the openings DTA1 and DTA2 may be improved.

The power voltage line 142 may be formed in the same layer as the connection electrode 141 provided in the active area AA. The power voltage line 142 may be disposed on the second organic film 132. In some cases, the power voltage line 142 may be located in the same layer as one of the electrodes forming the transistor TR, such as in the same layer as the first and second source-drain electrodes 124 and 125 of the transistor TR provided in the active area AA. The power voltage line 142 may be disposed on the first organic film 131.

Further, the power voltage line 142 may include one metal from among aluminum (Al), titanium (Ti), copper (Cu), chromium (Cr), molybdenum (Mo), and tungsten (W). In this case, when the power voltage line 142 patterned in the first mesh shape in the non-active area NA is covered only with transparent insulating films, glinting due to the patterned metal may be observed from above.

In order to prevent this, in the display device 1000 according to one implementation of the present disclosure, the light shielding layer 210B and 210C is disposed on the encapsulation layer 180 so as to overlap the power voltage line 142 having the first mesh shape, as shown in FIGS. 5 and 6. The light shielding layer 210B and 210C may be formed of a black organic material and include a light shielding component, such as black ink, carbon, or the like, so as to prevent reflection by the lower metal. In addition, as shown in FIG. 7, the light shielding layer 210B and 210C may have a greater line width than at least the line width of the first mesh shape of the power voltage line 142 to prevent the first mesh shape of the power voltage line 142 from being visible when looking at the non-active area NA at a different viewing angle or glinting due to side reflection.

The power voltage line 142 has a plurality of first openings DTA1 and DTA2, and the light shielding layer 210B and 210C may have second openings DTA3 that are smaller than each of the plurality of first openings DTA1 and DTA2 to correspond to the plurality of first openings DTA1 and DTA2.

Further, in FIGS. 5 and 6, the non-active area NA indicates the left and right sides of the substrate 110, and a gate driver GIP, a line block LB, the power voltage line area VSS, and the dam portion DAM may be sequentially arranged in a plane from the active area AA to an end line SUBE of the substrate 110.

The gate driver GIP includes a plurality of transistors, storage capacitors, etc., and may include the same stack as the transistors (TFTs) TR provided in the active area AA.

The line block LB includes a plurality of clock lines and a plurality of signal lines 242, 243, 244, and 245, and may be connected to the gate driver GIP and the pad portion PAD.

The gate driver GIP, the line block LB, and the power voltage line 142 may be provided in the same process as the transistors TR provided in the active area AA. The organic film PLN covers and protects the transistors (TFTs) and the stage 241 of the gate driver GIP. The power voltage line 142 can be positioned over the organic film PLN at the non-active area NA.

The transistors provided in the active area AA may have different stack structures depending on their functions, and may include source-drain metal layers of different layers, such as a first source-drain metal layer on the first organic film 131 and a second source-drain metal layer on the second organic film 132. Accordingly, as shown in FIG. 6, the power voltage line 142 may be formed of the second source-drain metal layer. The second source-drain metal layer may be located in the same layer as the connection electrode 141 in the active area AA.

Further, the second electrode (cathode) 153 disposed in the active area AA may extend to the non-active area NA and be conductively connected to the power voltage line 142. In this case, the second electrode 153 has conductive connections with the power voltage line 142 that occupies a large area in the non-active area NA located on the left and right sides of the substrate 110 in addition to supplying a power voltage through the pad portion PAD, thereby being capable of preventing brightness unevenness between areas while reducing the resistance of the second electrode 153.

In addition, at each connection portion where the power voltage line 142 and the second electrode 153 are connected, anode dummy patterns 251A and 251B may be further provided between the power voltage line 142 and the second electrode 153, thereby improving the electrical characteristics of the connection portion.

Here, the anode dummy patterns 251A and 251B may be located in the same layer as the first electrode 151.

The anode dummy patterns 251A and 251B may be disposed in a line or an island shape in a plurality of areas spaced apart from each other to overlap the first mesh-shaped power voltage line 142. The anode dummy patterns 251A and 251B are conductively connected to the first electrode 151 provided in each subpixel SP of the active area AA. The anode dummy patterns 251A and 251B function to conductively connect the power voltage line 142 to which a low-potential voltage is applied and the second electrode 153, and function independently of the first electrode 151.

The anode dummy patterns 251A and 251B may overlap the power voltage line 142, but may have a smaller area than the power voltage line 142. The anode dummy patterns 251A and 251B may be formed of the same material as the first electrode 151, and may include a reflective electrode. In order to prevent visibility by the anode dummy patterns 251A and 251B, the light shielding layer 210B and 210C on the anode dummy patterns 251A and 251B may have a greater width than the anode dummy patterns 251A and 251B.

The light shielding layer 210B and 210C may be disposed along the shape of the anode dummy patterns 251A and 251B. The light shielding layer 210B and 210C may cover the anode dummy patterns 251A and 251B.

The first organic film 131 and the second organic film 132 provided in the active area AA extend to overlap the power voltage line 142 in the non-active area NA, and the power voltage line 142 may be disposed on the second organic film 132.

The anode dummy patterns 251A and 251B are provided in contact holes penetrating the second organic film 132, and the second electrode 153 may be connected to the power voltage line 142 with the anode dummy patterns 251A and 251B interposed therebetween in the contact holes.

Further, when the planar gate driver GIP, the line block LB, the power voltage line 142, and the dam portion DAM are sequentially disposed in a plane in an area from the edge of the active area AA of the substrate 110 to the end line (edge) SUBE of the substrate 110, the power voltage line 142 may include a source-drain electrode layer located as a different layer from the gate driver GIP, the clock lines and the signal lines 242, 243, 244, and 245 of the line block LB, and metal patterns. Here, the source-drain electrode layer formed as the different layer may be located in the same layer as the connection electrode 141 connecting the transistor TR and the light emitting element ED in the subpixel SP.

A stage 241 of the gate driver GIP of FIGS. 5 and 6 is schematically illustrated, and the stage 241 may include a plurality of metal layers and an insulating layer between the plurality of metal layers.

The line block LB may include the plurality of clock lines and the signal lines 242, 243, 244, and 245.

The light shielding layer 210 corresponding to the stage 241 of the gate driver GIP may have a relatively greater line width than the light shielding layer 210A, 210B, and 210C formed in a second mesh shape corresponding to the clock lines and the signal lines 242, 243, 244, and 245 of the line block LB and the first mesh shape of the power voltage line area VSS. The light shielding layer 210, 210A, 210B, and 210C corresponding to the stage 241 of the gate driver GIP may overlap the gate driver GIP, the clock lines, and the power voltage line 142. The light shielding layer 210 provided with respect to the gate driver GIP may overlap corresponding components by the greatest width in the non-active area NA.

The power voltage line area VSS may include a first area VSSA overlapping the bank 160 and a second area VSSB not overlapping the bank 160. The bank 160 is provided in the first area VSSA, so that the anode dummy patterns 251A may not be connected to the second electrode 153. On the other hand, a bank end line BKE is located at the boundary between the first area VSSA and the second area VSSB, so that the anode dummy patterns 251B may be directly connected to the second electrode 153 in the second area VSSB.

The bank 160 is located around the emission areas EA and the transmission areas TA of the active area AA, extends to the non-active area NA to be provided in the gate driver GIP, the line block LB, and the first area VSSA of the power voltage line area VSS, and may function to protect the circuit configuration and the lines in the non-active area NA.

The first organic film 131 and the second organic film 132 may be located inside the dam portion DAM disposed in the non-active area NA. Thus, an edge of the organic film PLE can be positioned inside a plurality of dam patterns DM1, DM2, and DM3.

The dam portion DAM may include a plurality of dam patterns DM1, DM2, and DM3. Among the encapsulation layer 180, the organic encapsulation layer 182 is formed by applying a liquid material, and diffusion of the liquid material to the outside during the formation process may be prevented by the dam patterns DM1, DM2, and DM3 of the dam portion DAM. The dam patterns DM1, DM2, and DM3 may include, for example, at least one layer of the first or second organic film 131 or 132 or the bank 160. The dam patterns DM1, DM2, and DM3 may have a shape that surrounds the active area AA at the outside of the power voltage line 142 among the non-active area NA of the substrate 110.

Accordingly, a plurality of dam patterns DM1, DM2, and DM3 that surround the active area AA of the substrate 110 is provided outside the first mesh-shaped power voltage line 142, and the edge of the organic encapsulation layer 182 among the encapsulation layers 180 may be located between the plurality of dam patterns DM1, DM2, and DM3.

The line width of the light shielding layer 210B and 210C overlapping the power voltage line 142 is greater than or equal to the line width of the power voltage line 142, and the light shielding layer 210B and 210C may include openings corresponding to the power voltage line in the non-active area NA.

Hereinafter, implementations of the anode dummy patterns of the display device of the present disclosure will be described.

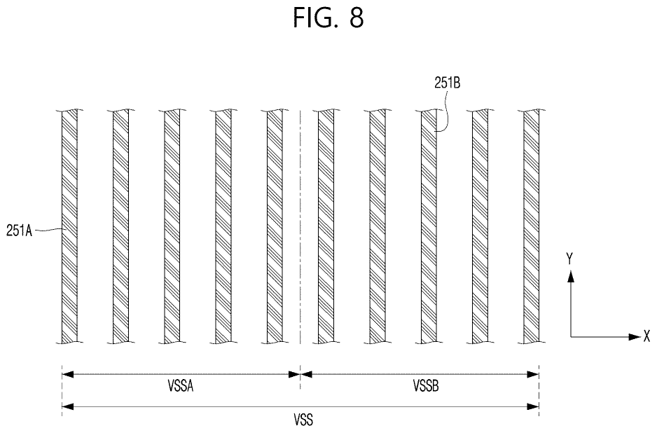

FIGS. 8 to 10 are plan views showing example implementations of the anode dummy patterns of FIG. 7.

As shown in FIG. 8, the anode dummy patterns 251A and 251B may be uniformly provided as lines in the Y-axis direction in the first area VSSA and the second area VSSB of the power voltage line area VSS.

Here, the respective anode dummy patterns 251A and 251B may be separated from each other. The anode dummy patterns 251A and 251B are separated from each other, but are connected to the first mesh-shaped power voltage line 142 disposed thereunder and the second electrode 153 disposed thereon that extends from the active area AA to the power voltage line region VSS of the non-active area NA.

The conductivity of the second electrode 153 is improved by the first mesh-shaped power voltage line 142 and the anode dummy patterns 251A and 251B connected thereto in an area occupied by the second electrode 153 among the non-active area NA, and the resistance of the second electrode 153 disposed in the active area AA is also reduced.

The line width of anode dummy patterns 251A and 251B of FIG. 8 may be equivalent to the line width in the Y-axis direction of the first mesh-shaped power voltage line 142 located thereunder. This is for stable connection between the power voltage line 142 and the anode dummy patterns 251A and 251B. In addition, the line width of the anode dummy patterns 251A and 251B may be smaller than the line width in the Y-axis direction of the corresponding light shielding layer 210B and 210C disposed thereabove. This is to allow the light shielding layer 210B and 210C to prevent the anode dummy patterns 251A and 251B from being visible from the outside.

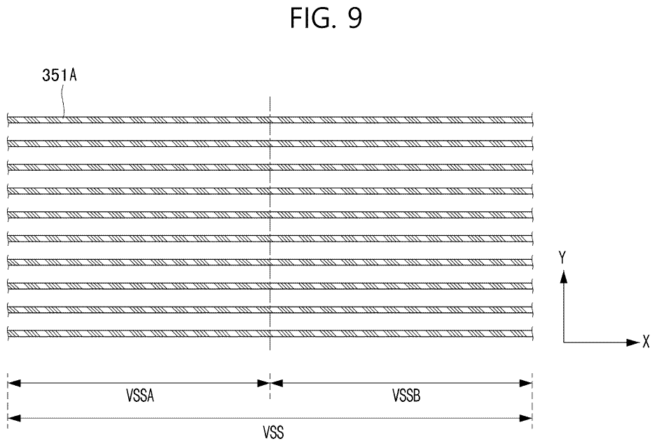

As shown in FIG. 9, anode dummy patterns 351A may be uniformly provided as lines in the X-axis direction in the first area VSSA and the second area VSSB of the power voltage line area VSS.

Here, the respective anode dummy patterns 351A may be formed to be separated from each other. The anode dummy patterns 351A are spaced apart from each other, but are connected to the first mesh-shaped power voltage line 142 disposed thereunder and the second electrode 153 disposed thereon that extends from the active area AA to the power voltage line area VSS of the non-active area NA.

The conductivity of the second electrode 153 is improved by the first mesh-shaped power voltage line 142 and the anode dummy patterns 351A connected thereto in an area occupied by the second electrode 153 among the non-active area NA, and the resistance of the second electrode 153 disposed in the active area AA is also reduced.

The line width of anode dummy patterns 351A of FIG. 9 may be equivalent to the line width in the X-axis direction of the first mesh-shaped power voltage line 142 located thereunder. This is for stable connection between the power voltage line 142 and the anode dummy patterns 351A. In addition, the line width of the anode dummy patterns 351A may be smaller than the line width in the X-axis direction of the corresponding light shielding layer 210B and 210C disposed thereabove. This is to allow the light shielding layer 210B and 210C to prevent the anode dummy patterns 351A from being visible from the outside.

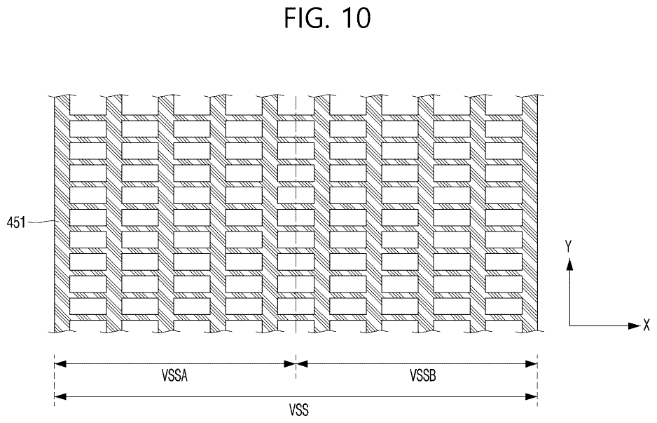

As shown in FIG. 10, anode dummy patterns 451 may be uniformly provided in the shape of a third mesh pattern in the first area VSSA and the second area VSSB of the power voltage line area VSS.

Here, the respective anode dummy patterns 451 are connected to each other.

The conductivity of the second electrode 153 is improved by the first mesh-shaped power voltage line 142 and the anode dummy patterns 451 connected thereto in an area occupied by the second electrode 153 among the non-active area NA, and the resistance of the second electrode 153 disposed in the active area AA is also reduced.

At least one of the line widths of the anode dummy patterns 451 of FIG. 10 in the X-axis direction and the Y-axis direction may be equivalent to the line width in the X-axis direction or the line width in the Y-axis direction of the first mesh-shaped power voltage line 142 located thereunder. This is for stable connection between the power voltage line 142 and the anode dummy patterns 451. In addition, the line width in each of the X-axis direction and the Y-axis direction of the anode dummy patterns 451 may be smaller than the line width in a corresponding one of the X-axis direction and the Y-axis direction of the corresponding light shielding layer 210B and 210C disposed thereabove. This is to allow the light shielding layer 210B and 210C to prevent the anode dummy patterns 451 from being visible from the outside.

An example in which the light shielding layer 210 and the color filter 220 are directly formed on the encapsulation layer 180 of the display device 1000 has been described above. However, the display device according to the implementations of the present disclosure is not limited thereto. The display device 1000 according to one implementation of the present disclosure has the power voltage line 142 provided in a mesh shape having openings to increases the transmittance of the non-active area NA, and the light shielding layer 210 formed in a mesh shape on the encapsulation layer 180 covering the power voltage line 142, thereby being capable of preventing the power voltage line 142 from being visible due to patterning.

The above-described display device 1000 of one implementation of the present disclosure may be implemented by applying mesh-shaped patterning to the structures of the power voltage line 142, the anode dummy patterns 251A and 251B, 351A, or 451, and the light shielding layer 210B and 210C without adding a separate material or process, thereby being capable of reducing production energy required for addition of a manufacturing process to produce the display device 1000, reducing generation of greenhouse gases, and thus implementing environmental, social, and governance (ESG).

In addition, the active area AA may be changed to another form as long as the non-active area NA has an optical effect due to the above-described structural features.

Hereinafter, a display device 1000 according to another implementation of the present disclosure will be described.

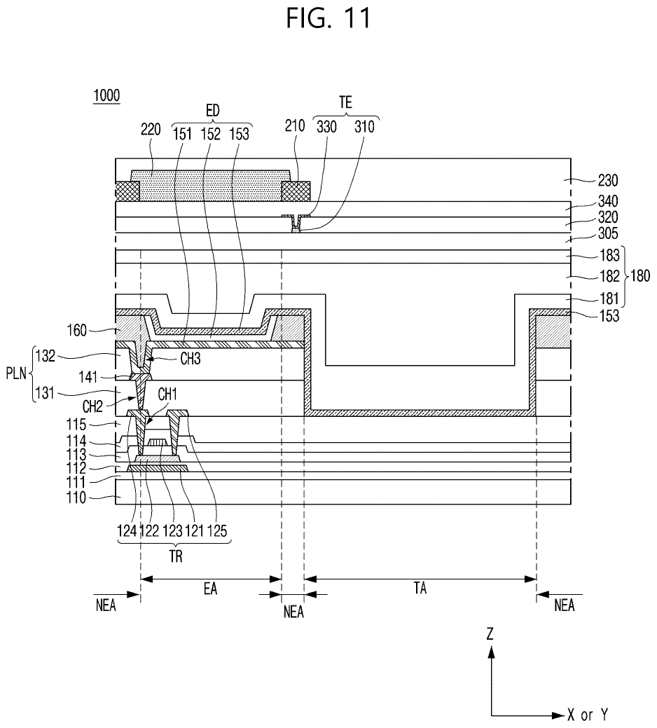

FIG. 11 is a cross-sectional view showing an example of the display device according to another implementation of the present disclosure.

As shown in FIG. 11, a touch sensor may be included between the encapsulation layer 180, and the light shielding layer 210 and the color filter 220 in the active area AA.

Therefore, the touch sensor provided on the encapsulation layer 180 to detect external touch is disposed on the flat encapsulation layer 180, and may include, for example, a touch buffer film 305, a sensor electrode TE, a touch insulating film 320, and a touch protective film 340.

Each of the touch buffer film 305, the touch insulating film 320, and the touch protective film 340 may be formed to include at least one of an inorganic insulating film or an organic insulating film.

In addition, the sensor electrode TE may include a bridge electrode 310 located on the touch buffer film 305, and a touch electrode 330 connected to the bridge electrode 310 through a touch contact hole formed through the touch insulating film 320 to expose the upper surface of the bridge electrode 310. The touch electrode 330 and the bridge electrode 310 may include metal, and may be covered by the light shielding layer 210 to prevent reflection visibility caused by the metal.

Further, in the structure including the touch sensor, a non-active area NA located on the left and right sides of a substrate 110 may have the power voltage line 142, the anode dummy patterns 251A and 251B, 351A, or 451, and the light shielding layer 210B and 210C that have been described in FIGS. 5 and 10. Here, at least one of the touch buffer film 305, the touch insulating film 320, or the touch protective film 340 of the touch sensor may be further provided between the encapsulation layer 180 and the light shielding layer 210B and 210C in the non-active area NA.

The above-described display device 1000 of another implementation of the present disclosure may be implemented by applying mesh-shaped patterning to the structures of the power voltage line 142, the anode dummy patterns 251A and 251B, 351A, or 451, and the light shielding layer 210B and 210C without adding a separate material or process, thereby being capable of reducing production energy required for addition of any manufacturing process to produce the display device 1000, reducing generation of greenhouse gases, and thus implementing environmental, social, and governance (ESG). In addition, the transmittance of the non-active area NA may also be improved even in the structure including the touch sensor of the display device 1000.

A display device according to one implementation of the present disclosure may comprise a substrate comprising a display area comprising a plurality of subpixels and a non-display area to surround the display area, a power voltage line in a first mesh shape and disposed at the non-display area, an encapsulation layer at an entirety of the display area and a part of the non-display area in which the power voltage line is disposed and a light shielding layer on the encapsulation layer to overlap the power voltage line.

In a display device according to one implementation of the present disclosure, the light shielding layer may be disposed in a second mesh shape to overlap an entirety of the power voltage line.

In a display device according to one implementation of the present disclosure, the light shielding layer may have a greater width than a width of the power voltage line at each area corresponding to the power voltage line.

In a display device according to one implementation of the present disclosure, the power voltage line may have a plurality of first openings, and the light shielding layer has second openings configured to be smaller than each of the plurality of first openings corresponding to the plurality of first openings.

In a display device according to one implementation of the present disclosure, the display area may further comprise a transmission area. Each of the plurality of the subpixel may comprise a transistor on the substrate, and a light emitting element connected to the transistor. The light emitting element may comprise an anode, an intermediate layer, and a cathode. The cathode may extend to the non-display area to be conductively connected to the power voltage line. The anode of the light emitting element does not overlap he transmission area.

In a display device according to one implementation of the present disclosure, the power voltage line may be connected to an anode dummy pattern of the same layer as the anode.

In a display device according to one implementation of the present disclosure, the anode dummy pattern may overlap the first mesh-shaped power voltage line, and is disposed in a line shape or an island shape at a plurality of areas spaced apart from each other.

In a display device according to one implementation of the present disclosure, the anode dummy pattern may overlap the power voltage line, and has a smaller area than the power voltage line.

In a display device according to one implementation of the present disclosure, the light shielding layer may be disposed along a shape of the anode dummy pattern.

In a display device according to one implementation of the present disclosure, a first organic film and a second organic film may be sequentially provided between the transistor and the light emitting element. The first organic film and the second organic film may extend to the non-display area to overlap the power voltage line. the power voltage line may be disposed on the first organic film.

In a display device according to one implementation of the present disclosure, the anode dummy pattern may be provided in at least one contact hole through the second organic film. The cathode may be connected to the power voltage line with the anode dummy patterns interposed therebetween in the contact holes.

In a display device according to one implementation of the present disclosure, the first organic film and the second organic film may be located inside a dam pattern disposed in the non-display area.

In a display device according to one implementation of the present disclosure, the transistor may comprise an oxide semiconductor.

In a display device according to one implementation of the present disclosure, the encapsulation layer may comprise a first inorganic encapsulation layer, an organic encapsulation layer, and a second inorganic encapsulation layer. The light shielding layer may be disposed on the second inorganic encapsulation layer.

In a display device according to one implementation of the present disclosure, a plurality of dam patterns configured to surround an edge of the substrate may be provided outside the power voltage line in the first mesh shape, and an edge of the organic encapsulation layer may be located between the plurality of dam patterns.

In a display device according to one implementation of the present disclosure, a line width of the light shielding layer configured to overlap the power voltage line may be greater than or equal to a line width of the power voltage line. And the light shielding layer may comprise openings corresponding to opening of the power voltage line in the non-display area.

In a display device according to one implementation of the present disclosure, a gate driver, clock lines, the power voltage line, and dam patterns may be sequentially arranged in a plane between an area from an edge of the display area of the substrate to an edge of the substrate. The power voltage line may comprise a source-drain electrode layer located at a different layer from the gate driver and the clock lines and the source-drain electrode layer may be located at a same layer as a connection electrode configured to connect a transistor and a light emitting element at each of the subpixels.

In a display device according to one implementation of the present disclosure, the light shielding layer may overlap the gate driver, the clock lines, and the power voltage line, and overlaps the gate driver with a greatest width in the non-display area.

In a display device according to one implementation of the present disclosure each of the subpixel comprises a transistor on the substrate, a light emitting element connected to the transistor, and a bank to overlap an edge of an anode of the light emitting element.

The non-display area may comprise anode dummy patterns disposed in the same layer as the anode and connected to the power voltage line.

The power voltage line may comprise a first area configured to overlap the bank and a second area configured not to overlap the bank.

A cathode of the light emitting element may extend to an area comprising the first area and the second area among the non-display area to be connected to the anode dummy patterns in the second area.

In a display device according to one implementation of the present disclosure, an organic protective film may be further provided on the light shielding layer.

As is apparent from the above description, a display device according the implementations of the present disclosure has the following effects.

A display device of the implementations of the present disclosure may apply a mesh structure having openings to a power voltage line in a non-active area including power voltage lines and circuits to have improved transmittance.

A display device of the implementations of the present disclosure may increase a transmittance area through the mesh structure of a power voltage line in a non-active area to have transmittance similar to that of an active area and improve a sense of heterogeneity.

A display device of the implementations of the present disclosure may include a light shielding layer that cover metal patterns having connections with power voltage lines in a non-active area to prevent reflection visibility caused by metal patterns disposed on wirings or glinting that occurs at a different viewing angle.

A display device of the implementations of the present disclosure may increase transmittance not only in an active area but also in a non-active area to increase pure transmittance without visibility, such as diffraction or interference, of an object or an image located on a surface of the display device opposite a display surface throughout the entire area.

A display device of the implementations of the present disclosure may prevent an increase in the resistance of a power voltage line having a mesh structure through a connection structure among the power voltage line, anode patterns, and a cathode extension in a non-active area, and may reduce the resistance of a cathode to uniformize the voltage of the cathode throughout an active area and improve image quality.

A display device according to the implementations of the present disclosure may pattern a power voltage line, an anode, a cathode, and a light shielding layer that are provided in an active area to use these components in a non-active area, thereby being capable of improving the transmittance of the non-active area without adding a separate material or process. Therefore, it is possible to reduce greenhouse gases generated by adding layers or processes, and implement process optimization. In addition, the transmittance of the display device may be improved without adding processes, sustainability may be obtained, and thus, the environmental, social, and governance (ESG) effects may be achieved.

A display device according to the implementations of the present disclosure may utilize the same process and minimize occurrence of defects in the display device, thereby being capable of reducing production energy required to produce the display device, reducing use of hazardous production materials or regulated substances, and being thus advantageous for recycling.

Through the above description, it should be apparent to those skilled in the art that various changes and modifications are possible without departing from the technical spirit of the present disclosure. Therefore, the technical scope of the present disclosure should not be limited to the above detailed description, but should be defined by the scope of the claims.

1. A display device comprising:
a substrate comprising a display area and a non-display area outside a periphery of the display area, the display area comprising a plurality of subpixels;
a power voltage line arranged in a first mesh shape and disposed at the non-display area;
an encapsulation layer disposed at an entirety of the display area and at a part of the non-display area in which the power voltage line is disposed; and
a light shielding layer on the encapsulation layer and overlapping the power voltage line.

2. The display device according to claim 1, wherein the light shielding layer is disposed in a second mesh shape and overlapping an entirety of the power voltage line.

3. The display device according to claim 2, wherein a width of the light shielding layer is greater than a width of the power voltage line at each area corresponding to the power voltage line.

4. The display device according to claim 1, wherein the power voltage line has a plurality of first openings, and the light shielding layer has a plurality of second openings corresponding to the plurality of first openings,
wherein each of the plurality of second openings is configured to be smaller than a respective one of the plurality of first openings.

5. The display device according to claim 1, wherein:
the display area further comprises a transmission area,
each of the plurality of subpixels comprises a transistor on the substrate, and a light emitting element connected to the transistor,
the light emitting element comprises an anode, an intermediate layer, and a cathode,
the anode of the light emitting element is not disposed in the transmission area, and
the cathode extends to the non-display area and is conductively connected to the power voltage line.

6. The display device according to claim 5, wherein the power voltage line is connected to an anode dummy pattern of the same layer as the anode.

7. The display device according to claim 6, wherein the anode dummy pattern overlaps the power voltage line having the first mesh shape, and
wherein the anode dummy pattern is disposed in a line shape or an island shape at a plurality of areas spaced apart from each other.

8. The display device according to claim 6, wherein the anode dummy pattern overlaps the power voltage line, and has a smaller area than the power voltage line.

9. The display device according to claim 6, wherein the light shielding layer is disposed along a shape of the anode dummy pattern.

10. The display device according to claim 6, wherein:
a first organic film and a second organic film are sequentially provided between the transistor and the light emitting element,
the first organic film and the second organic film extend to the non-display area to overlap the power voltage line, and
the power voltage line is disposed on the first organic film.

11. The display device according to claim 10, wherein:
the anode dummy pattern is provided in at least one contact hole through the second organic film, and
the cathode is connected to the power voltage line with the anode dummy patterns interposed therebetween in the contact holes.

12. The display device according to claim 10, wherein the first organic film and the second organic film are located inside a dam pattern disposed in the non-display area.

13. The display device according to claim 5, wherein the transistor comprises an oxide semiconductor.

14. The display device according to claim 1, wherein:
the encapsulation layer comprises a first inorganic encapsulation layer, an organic encapsulation layer, and a second inorganic encapsulation layer, and
the light shielding layer is disposed on the second inorganic encapsulation layer.

15. The display device according to claim 14, wherein a plurality of dam patterns configured to surround an edge of the substrate is provided outside the power voltage line in the first mesh shape, and an edge of the organic encapsulation layer is located between the plurality of dam patterns.

16. The display device according to claim 1, wherein:
a line width of the light shielding layer configured to overlap the power voltage line is greater than or equal to a line width of the power voltage line, and
the light shielding layer comprises openings corresponding to opening of the power voltage line in the non-display area.

17. The display device according to claim 1, wherein:
a gate driver, clock lines, the power voltage line, and dam patterns are sequentially arranged in a plane between an area from an edge of the display area of the substrate to an edge of the substrate,
the power voltage line comprises a source-drain electrode layer located at a different layer from the gate driver and the clock lines, and
the source-drain electrode layer is located at a same layer as a connection electrode configured to connect a transistor and a light emitting element at each of the plurality of subpixels.

18. The display device according to claim 17, wherein the light shielding layer overlaps the gate driver, the clock lines, and the power voltage line, and overlaps the gate driver with a greatest width in the non-display area.

19. The display device according to claim 1, wherein:
each of the plurality of subpixels comprises a transistor on the substrate, a light emitting element connected to the transistor, and a bank to overlap an edge of an anode of the light emitting element,
the non-display area comprises anode dummy patterns disposed in the same layer as the anode and connected to the power voltage line,
the power voltage line comprises a first area configured to overlap the bank and a second area configured not to overlap the bank, and
a cathode of the light emitting element extends to an area comprising the first area and the second area among the non-display area to be connected to the anode dummy patterns in the second area.

20. The display device according to claim 19, wherein an organic protective film is further provided on the light shielding layer.
